(19) United States
(12) Patent Application Publication
(10) Pub. No.: US 2026/0044098 A1
(43) Pub. Date: Feb. 12, 2026

(54) IMAGE HEATING APPARATUS AND IMAGE FORMING APPARATUS

(71) Applicant: CANON KABUSHIKI KAISHA, Tokyo (JP)

(72) Inventor: YUYA HIRANO, Kanagawa (JP)

(21) Appl. No.: 19/290,420

(22) Filed: Aug. 5, 2025

(30) Foreign Application Priority Data
Aug. 9, 2024 (JP) 2024-134496

(51) Int. Cl. G03G 15/20; G01K 3/00; G01R 31/34; G03G 15/00

(52) U.S. Cl. CPC G03G 15/2039; G01K 3/005; G01R 31/34; G03G 15/2053; G03G 15/2064; G03G 15/5004; G03G 2215/2035

(57) ABSTRACT

An image heating apparatus includes a cylindrical rotary member, a magnetic core, an exciting coil wound around the magnetic core along the axis direction of the rotary member, an inverter configured to flow alternating current in the exciting coil, a control portion configured to control the inverter to cause alternating current to flow through the exciting coil so that alternating magnetic flux is generated in the magnetic core and the rotary member is induction-heated, and a detection coil in which induced electromotive force is produced by the induced electromotive force being electromagnetically induced by the alternating magnetic flux. The control portion is configured to change driving frequency of the inverter. The control portion is configured to stop or reduce electric power supplied from the inverter to the exciting coil, in a case where a value of the induced electromotive force becomes greater than a predetermined value.

### BACKGROUND

### Field of the Technology

The present disclosure relates to an image heating apparatus that heats an image formed on a recording material, and to an image forming apparatus.

### Description of the Related Art

An electrophotographic image forming apparatus, such as a printer or a copying machine, transfers a toner image that corresponds to image data, to a recording material, such as a recording sheet or an OHP sheet; and then causes a fixing apparatus to fix the toner image transferred to the recording material, to the recording material by heating and pressing the toner image. In general, such a heating-type fixing apparatus includes a heating element that serves as a heat source, a power source that supplies electric power to the heating element, a temperature detection portion that detects the temperature in the vicinity of the heating element, and a control portion that controls the current that flows in the heating element.

Japanese Patent Application Publication No. 2011-003396 discloses a method that limits the electric power in the above-described configuration so that the electric power having a value equal to or greater than a predetermined value is not supplied to the heating element. The method is performed for preventing excessive electric power from being supplied to the heating element in a case where an error or the like occurs in the temperature detection portion.

In addition, as a heating system of the fixing apparatus, the electromagnetic-induction heating system is known. In the electromagnetic-induction heating system, an alternating magnetic field generated by a magnetic-field generating portion is provided to the interior of an electromagnetic-induction heat-generating rotary member, and the heat-generating rotary member is heated by Joule heat generated by the eddy-current loss that occurs in the heat-generating rotary member. Japanese Patent Application Publication No. 2016-24348 discloses a method that changes the longitudinal temperature distribution of the heat-generating rotary member in the fixing apparatus having the electromagnetic-induction heating system, by changing the frequency of the alternating current supplied to an exciting coil that generates the alternating magnetic field.

### SUMMARY

According to a first aspect of the present disclosure, an image heating apparatus configured to heat an image formed on a recording material, the image heating apparatus includes a cylindrical rotary member having conductivity, a magnetic core disposed in the rotary member and configured to form an open magnetic path in an axis direction of the rotary member, an exciting coil wound around the magnetic core along the axis direction of the rotary member, an inverter configured to flow alternating current in the exciting coil, a control portion configured to control the inverter to cause alternating current to flow through the exciting coil so that alternating magnetic flux is generated in the magnetic core and the rotary member is induction-heated, and a detection coil in which induced electromotive force is produced by the induced electromotive force being electromagnetically induced by the alternating magnetic flux. The control portion is configured to change driving frequency of the inverter. The control portion is configured to stop or reduce electric power supplied from the inverter to the exciting coil, in a case where a value of the induced electromotive force becomes greater than a predetermined value.

According to a second aspect of the present disclosure, an image heating apparatus configured to heat an image formed on a recording material, the image heating apparatus includes a cylindrical rotary member having conductivity, a magnetic core disposed in the rotary member and configured to form an open magnetic path in an axis direction of the rotary member, an exciting coil wound around the magnetic core along the axis direction of the rotary member, an inverter configured to flow alternating current in the exciting coil, a control portion configured to control the inverter to cause alternating current to flow through the exciting coil so that alternating magnetic flux is generated in the magnetic core and the rotary member is induction-heated, a detection coil in which induced electromotive force is produced by the induced electromotive force being electromagnetically induced by the alternating magnetic flux, and a temperature detection portion configured to detect a temperature of the rotary member. The control portion is configured to compare a temperature of the rotary member detected by the temperature detection portion in a predetermined period of time and an induced electromotive force detected by the detection coil in the predetermined period of time, and stop or reduce electric power supplied from the inverter to the exciting coil, in a case where a relationship between the temperature of the rotary member and the induced electromotive force is different from a predetermined relationship.

According to a third aspect of the present disclosure, an image heating apparatus configured to heat an image formed on a recording material, the image heating apparatus includes a cylindrical rotary member having conductivity, a magnetic core disposed in the rotary member and configured to form an open magnetic path in an axis direction of the rotary member, an exciting coil wound around the magnetic core along the axis direction of the rotary member, an inverter configured to flow alternating current in the exciting coil, a control portion configured to control the inverter to cause alternating current to flow through the exciting coil so that alternating magnetic flux is generated in the magnetic core and the rotary member is induction-heated, a first heat-generation-amount detection portion configured to detect an amount of heat generation of a center portion of the rotary member, and a second heat-generation-amount detection portion configured to detect an amount of heat generation of an end portion of the rotary member. the control portion is configured to correct driving frequency of the inverter for increasing the driving frequency in a case where a difference between the amount of heat generation of the center portion of the rotary member obtained based on a result detected by the first heat-generation-amount detection portion when the control portion drives the inverter with a predetermined frequency and driving duty ratio and the amount of heat generation of the end portion of the rotary member obtained based on a result detected by the second heat-generation-amount detection portion when the control portion drives the inverter with the predetermined frequency and driving duty ratio is greater than a predetermined difference.

Features of the present disclosure will become apparent from the following description of embodiments with reference to the attached drawings. The following description of embodiments is described by way of example.

### BRIEF DESCRIPTION OF THE DRAWINGS

FIG. 1 is a schematic cross-sectional view of an image forming apparatus of a first embodiment.

FIG. 2 is a diagram of a model of a cross section of a fixing apparatus.

FIG. 3 is a diagram of a model of a front face of the fixing apparatus.

FIG. 4 is a perspective view of the fixing apparatus and a connection-circuit block diagram.

FIG. 5 is a schematic diagram illustrating a relationship between an exciting coil current and a magnetic field.

FIG. 6 is a diagram illustrating heat generation distribution in a longitudinal direction of a fixing film.

FIG. 7A is a diagram illustrating a relationship between the electric power applied to an exciting coil and the voltage detected by a detection coil disposed in a center portion of the fixing film.

FIG. 7B is a diagram illustrating a relationship between the electric power applied to the exciting coil and the voltage detected by a detection coil disposed in an end portion of the fixing film.

FIG. 8 is a flowchart diagram of control of limiting the amount of heat generation of the fixing film.

FIG. 9 is a flowchart diagram of control of limiting the amount of heat generation in a modification.

FIG. 10 is a flowchart diagram of a frequency-correction determination process.

FIG. 11 is a perspective view of a fixing apparatus of a second embodiment and a connection-circuit block diagram.

FIG. 12 is a graph illustrating a relationship between the film temperature and the induced electromotive force.

FIG. 13 is a flowchart diagram of control of limiting the amount of heat generation of a fixing film of the second embodiment.

FIG. 14 is a flowchart diagram of a process of determining an abnormal amount of temperature rise.

### DESCRIPTION OF THE EMBODIMENTS

In the fixing apparatus as described in Japanese Patent Application Publication No. 2016-24348 and having the electromagnetic-induction heating system, the temperature distribution of the rotary member in the longitudinal direction changes in accordance with the frequency of alternating current supplied to the exciting coil. Thus, even if the electric power is limited in a fixed manner as described in Japanese Patent Application Publication No. 2011-003396, it is difficult to appropriately control the temperature of the rotary member because the temperature of each portion (formed in the longitudinal direction) of the rotary member changes in accordance with the frequency of alternating current.

The present disclosure provides an image heating apparatus and an image forming apparatus that can appropriately control the temperature of the rotary member.

### First Embodiment

### Schematic Configuration of Image Forming Apparatus

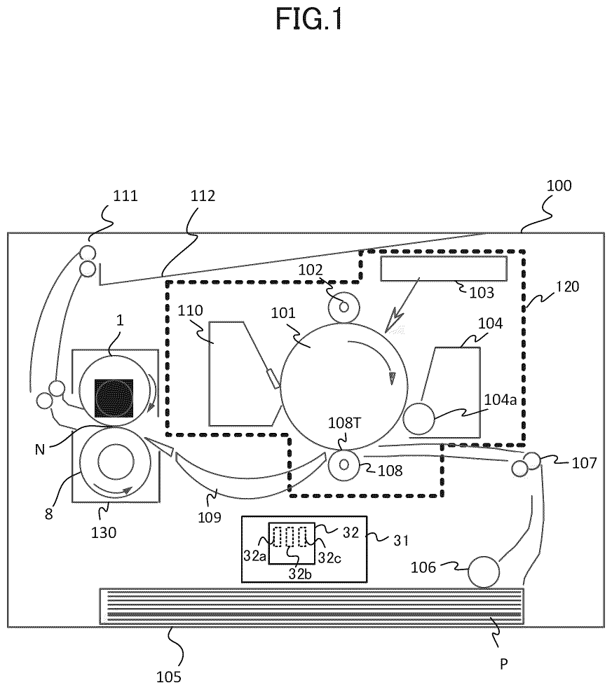

Hereinafter, a fixing apparatus that serves as an image heating apparatus of an embodiment of the present disclosure and an image forming apparatus 100 that includes the fixing apparatus will be described with reference to the accompanying drawings. As illustrated in FIG. 1, the image forming apparatus 100 is an electrophotographic laser-beam printer; and includes a feeding cassette 105, a feeding roller 106, a registration roller 107, an image forming portion 120, a fixing apparatus 130, and a control portion 31. The feeding cassette 105 is a recording-material support portion that supports a recording material P, and stacks and stores the recording material P. The feeding roller 106 is a feeding portion that feeds the recording material P stored in the feeding cassette 105; and separates the recording material P stacked and stored by the feeding cassette 105, from others, one by one, and feeds the recording material P. The registration roller 107 is a recording-material conveyance portion that conveys the recording material p fed from the feeding cassette 105, toward the image forming portion 120; and conveys the recording material P in synchronization with a timing of image formation performed by the image forming portion 120.

The image forming portion 120 forms an image on the recording material P; and includes a photosensitive drum 101, a charging roller 102, an exposure apparatus 103, a developing apparatus 104, a transfer roller 108, and a cleaning apparatus 110. The charging roller 102, the exposure apparatus 103, the developing apparatus 104, the transfer roller 108, and the cleaning apparatus 110 are disposed around the photosensitive drum 101. The charging roller 102 uniformly charges the photosensitive drum 101 rotated at a predetermined speed in a direction indicated by an arrow in FIG. 1, so that the photosensitive drum 101 has predetermined polarity and electric potential. The exposure apparatus 103 is a laser-beam scanner, and scans and exposures the surface of the photosensitive drum 101 on which the charging process is performed (the surface of the photosensitive drum 101 is irradiated with the laser beam by the exposure apparatus 103). Specifically, the exposure apparatus 103 scans and exposures the surface of the photosensitive drum 101 by outputting a laser beam that is ON-OFF modulated in accordance with a time-series electric digital pixel signal sent from an external apparatus, such as a host computer, and representing the image information for the printing. The developing apparatus 104 includes a developing roller 104a that supplies developer (toner) to the surface of the photosensitive drum 101 and develops, by using the developer, an electrostatic latent image formed on the surface of the photosensitive drum 101 by the exposure apparatus 103. The transfer roller 108, together with the photosensitive drum 101, forms a transfer nip 108T for transferring images, in a transfer portion. Thus, a toner image formed on the photosensitive drum 101 is transferred to the recording material P by a transfer voltage being applied to the transfer roller 108. The cleaning apparatus 110 is disposed downstream of the above-described transfer nip 108T in the rotational direction of the photosensitive drum 101; and removes transfer residual toner left on the photosensitive drum 101, paper dust, and the like.

The fixing apparatus 130 is an image heating apparatus that has the electromagnetic-induction heating system; and includes a fixing film 1 that serves as a rotary heating member, and a pressing roller 8 that, together with the fixing film 1, forms a fixing nip N. The fixing apparatus 130, in which the fixing film 1 and the pressing roller 8 form the fixing nip N, fixes an unfixed toner image transferred to the recording material P, to the recording material P in the fixing nip N, by heating and pressing the unfixed toner image.

The control portion 31 is a controller that controls each unit of the above-described image forming apparatus 100; and includes a ROM 32a and a RAM 32b that serve as a storage portion, a timer 32c, a central processing unit (CPU) 32 that serves as a computing portion, and various types of input/output control circuits (not illustrated).

In the image forming apparatus 100 configured in this manner, if a feeding start signal is sent from the control portion 31 to the feeding roller 106, the feeding roller 106 is driven, and the recording material P stored in the feeding cassette 105 is separated, one by one, from other sheets and fed. If the recording material P is fed from the feeding cassette 105, the recording material P is conveyed to the transfer nip 108T by the registration roller 107 at a timing at which a toner image formed on the photosensitive drum 101 is conveyed to the transfer nip 108T. Then the toner image is transferred onto the recording material P in the transfer nip 108T by a transfer voltage (transfer bias) whose polarity is opposite to the polarity of toner being applied to the transfer roller 108.

After the toner image is transferred onto the recording material P, the recording material P that bears the unfixed toner image is conveyed to the fixing apparatus 130 by a pre-fixing conveyance guide 109. In the fixing apparatus 130, the toner image is pressed and heated, so that the toner image is fixed to the recording material P. The recording material P to which the toner image has been fixed is discharged from a discharging port 111 onto a discharging tray 112 that serves as a discharging portion.

### Configuration of Fixing Apparatus

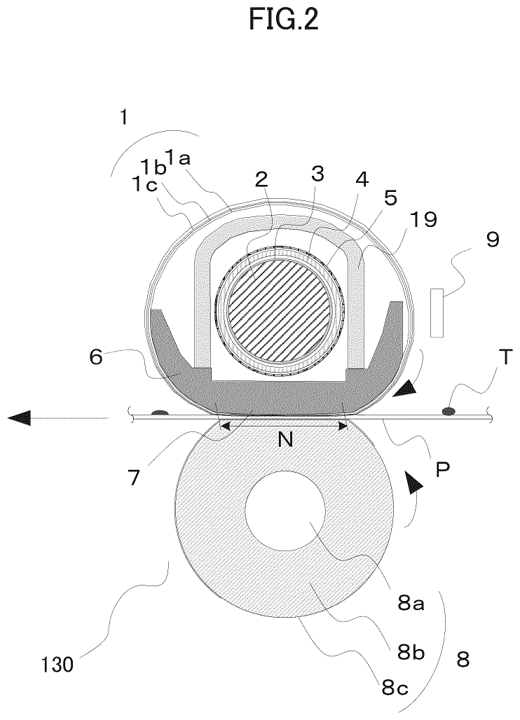

Next, a configuration of the fixing apparatus 130 will be described with reference to FIGS. 2 to 4. As illustrated in FIG. 2, the pressing roller 8 that serves as a pressing member includes a core metal 8a, a heat-resisting elastic-material layer 8b (hereinafter abbreviated as an elastic-material layer 8b), and a release layer 8c. The elastic-material layer 8b is coaxially formed, like a roller, around the core metal such that the core metal is coated with the elastic-material layer 8b. The release layer 8c is formed as a surface layer. Both end portions of the above-described core metal 8a are rotatably held by side plates of a chassis (not illustrated) of the fixing apparatus 130 via conductive bearings (the core metal 8a is disposed between the side plates of the chassis), so that the pressing roller 8 can rotate.

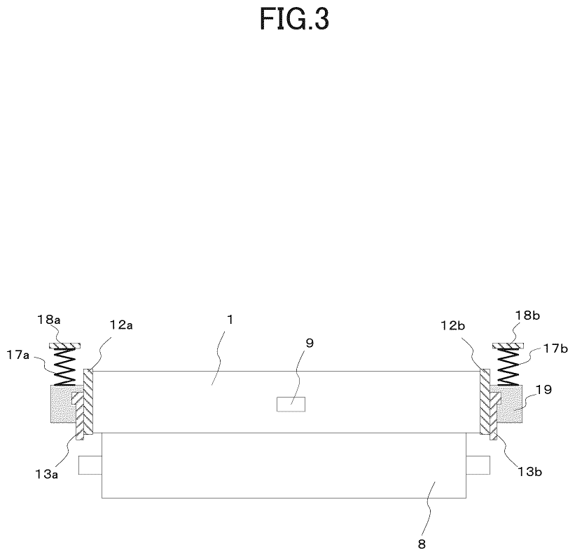

The fixing film 1 is a cylindrical rotary member that has conductivity. In the fixing film 1, a sleeve guide member 6 and a pressing stay 19 are disposed so as to extend in the longitudinal direction (i.e., the rotation axis direction). The pressing stay 19 is disposed above the sleeve guide member 6, and both end portions of the pressing stay 19 project from the fixing film 1. The sleeve guide member 6 is disposed in a lower portion of the fixing film 1, and holds the fixing film 1 on the inner circumference side. As illustrated in FIG. 3, flange members 12a and 12b are attached to both end portions of the sleeve guide member 6. Each of the flange members 12a and 12b includes a cylindrical portion, and a flange portion formed so as to project from the cylindrical portion in a radial direction. Each end portion of the fixing film 1 is externally fitted to a corresponding one of the above-described cylindrical portions such that the fixing film 1 can rotate. In addition, the positions (i.e., right and left positions) of the flange members 12a and 12b in the longitudinal direction are regulated by restricting members 13a and 13b. Each of the above-described flange portions is in contact with a corresponding one of the end portions of the fixing film 1, and restricts the fixing film 1 from moving in the longitudinal direction. In this manner, the fixing film 1 is positioned in the longitudinal direction.

In addition, a pressing spring 17a is disposed, contracted, between one end portion of the pressing stay 19 and a spring receiving member 18a disposed on the chassis side of the fixing apparatus 130, and a pressing spring 17b is disposed, contracted, between the other end portion of the pressing stay 19 and a spring receiving member 18b disposed on the chassis side of the fixing apparatus 130. Thus, the pressing stay 19 is urged downward (the pressing-down force is applied). In this configuration, the bottom surface of the sleeve guide member 6 and the top surface of the pressing roller 8 are in pressure contact with each other via the fixing film 1, so that the fixing nip N that has a predetermined width is formed. In addition, the pressing roller 8 is rotated by a driving portion (not illustrated) in a direction (i.e., a counterclockwise direction) indicated by an arrow in FIGS. 1 and 2. The fixing film 1 is also applied with rotational force by the rotation of the pressing roller 8, via the frictional force.

As illustrated in FIG. 2, the fixing film 1 is a cylindrical rotary member having a composite structure and including a heat generating layer 1a, an elastic layer 1b, and a release layer 1c. The heat generating layer 1a has a diameter of 10 to 50 mm, serves as a base layer, and is made of a conductive member. The elastic layer 1b is laminated on the outer surface of the heat generating layer 1a, and the release layer 1c is laminated on the outer surface of the elastic layer 1b. The heat generating layer 1a is a metal film that has a film thickness of 10 to 50 μm. The elastic layer 1b is made of silicone rubber having a hardness of 20 degrees (JIS-A, load of 1 kg) and a thickness of 0.1 to 0.3 mm. The surface layer (release layer) 1c is a fluororesin tube that has a thickness of 10 to 50 μm. If the alternating magnetic flux is exerted on the heat generating layer 1a, the induced current occurs in the heat generating layer 1a, and the heat generating layer 1a generates heat. The heat is transmitted to the elastic layer 1b and the release layer 1c, so that the whole of the fixing film 1 is heated. Thus, if the recording material P passes through the fixing nip N, a toner image T formed on the recording material P is heated, and fixed to the recording material P.

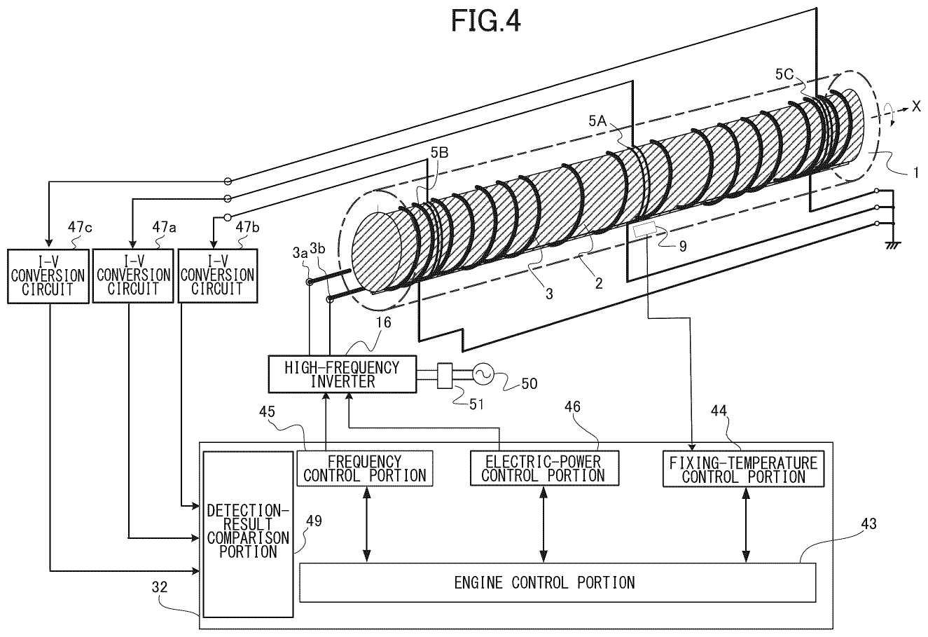

Next, the mechanism for exerting the alternating magnetic flux on the heat generating layer 1a and generating the induced current in the heat generating layer 1a will be described in detail. As illustrated in FIG. 2, in a center portion of the fixing film 1, a magnetic core 2 that serves as an example of a magnetic core, and an exciting coil 3 are disposed. As illustrated in FIG. 4, the magnetic core 2 is disposed so as to pass through the hollow portion of the fixing film 1, and forms a linear open magnetic path having magnetic poles. The material of the magnetic core 2 is a material having lower hysteresis loss and higher relative permeability. For example, the material of the magnetic core 2 is a high relative-permeability oxide or alloy, such as sintered ferrite, ferrite resin, amorphous alloy, or permalloy. The material of the magnetic core 2 may be a ferromagnetic material. Note that in the present embodiment, the magnetic core 2 is made of a sintered ferrite having a relative permeability of 1800, and has a cylindrical shape having a diameter of 5 to 30 mm and a longitudinal length of 240 mm. In another case, the magnetic core 2 may be formed by disposing a plurality of cores serially in the longitudinal direction. In this case, the longitudinal length of each core may be 30 mm.

The exciting coil 3 is formed by helically winding a common single conducting wire around the magnetic core 2 along the rotation axis direction of the fixing film 1. Specifically, the conducting wire is wound around the magnetic core 2 such that the interval of turns in an end portion of the core is made shorter than the interval of turns in a center portion of the core. For example, the exciting coil 3 is wound, 18 turns, around the magnetic core 2 having a longitudinal size of 240 mm. In this case, the interval of turns is 10 mm in an end portion of the core, 20 mm in a center portion of the core, and 15 mm in a portion of the core between the end portion and the center portion of the core. In this manner, the exciting coil 3 is wound around the magnetic core 2 in a direction that intersects an axis X of the magnetic core 2.

The exciting coil 3 is connected with a high-frequency inverter 16 via feeding contact portions 3a and 3b. The high-frequency inverter 16 is supplied, via an inlet 51, with alternating-current electric power from a commercial power source 50 disposed outside the image forming apparatus 100. The high-frequency inverter 16 converts the alternating-current electric power from the commercial power source 50, to high-frequency current; and supplies the high-frequency current to the exciting coil 3. That is, the high-frequency inverter 16 is an inverter that flows the alternating current in the exciting coil 3. By flowing the high-frequency alternating current in the exciting coil 3, the high-frequency inverter 16 can generate the alternating magnetic flux in a magnetic path formed by the magnetic core 2.

The basic principle of generating heat in the fixing apparatus 130 that has the induction-heating system is the same as that of a transformer. That is, the exciting coil 3 corresponds to a primary coil (with 18 turns) of the transformer on the input side, and the fixing film 1 corresponds to a secondary coil (with a single turn) of the transformer on the output side. In this configuration, if alternating-current voltage having a frequency of about 60 to 90 kHz is applied to the primary coil (i.e., the exciting coil 3), current flows in the primary coil. If the current flows in the primary coil (i.e., the exciting coil 3), the magnetic flux generated in a direction in which the magnetic flux passes through the fixing film 1 flows in the magnetic core 2, so that the induced electromotive force is produced in the secondary coil (i.e., the fixing film 1) by the magnetic flux. If the induced electromotive force is produced in the secondary coil (i.e., the fixing film 1), current flows along a circumferential direction of the fixing film 1. As a result, the fixing film 1 generates heat due to resistance loss of the fixing film 1, so that the fixing film 1 is induction-heated.

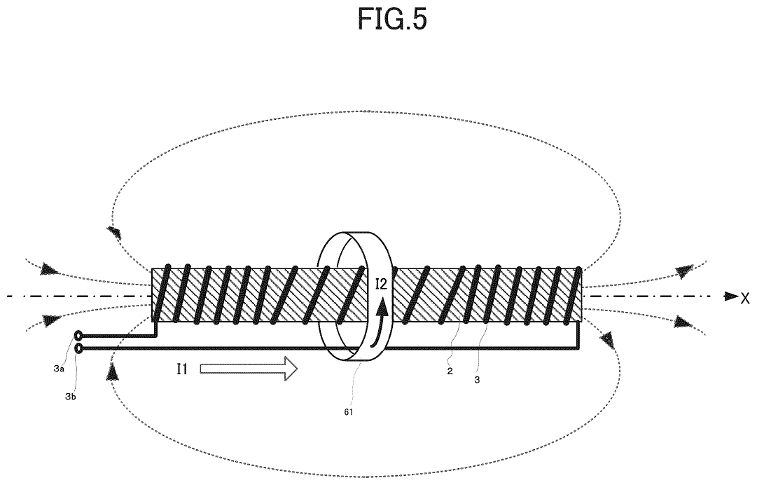

The description will be made more specifically. FIG. 5 is a diagram illustrating an instantaneous magnetic field in which the current that flows in the exciting coil 3 in a direction indicated by an arrow I1 is increasing. In FIG. 5, the magnetic core 2 functions as a member that forms a magnetic path by inducing lines of magnetic force produced by the exciting coil 3, into the magnetic core 2. Thus, the lines of magnetic force form a shape in which the lines of magnetic force pass through the magnetic path formed in the magnetic core 2 in a collective manner, disperse in one end portion of the magnetic core 2, and rejoin with each other at a point on an outer circumference and far from the point at which the lines of magnetic force disperse (some of the lines of magnetic force break at each of the end portions in FIG. 5 for convenience of illustration). Suppose that a cylindrical circuit 61 having a shorter longitudinal width is placed so as to surround the magnetic path perpendicularly. In the magnetic core, the alternating magnetic field (whose magnitude and direction change repeatedly with time) is formed.

In the circumferential direction of the circuit 61, the induced electromotive force is produced, depending on Faraday's law. In Faraday's law, the magnitude of induced electromotive force produced in the circuit 61 is proportional to the rate of change of the magnetic field that passes perpendicularly through the circuit 61. It can be considered that the heat generating layer 1a is constituted by a plurality of very short and cylindrical circuits 61 connected to each other in the longitudinal direction. Thus, an induced electromotive force Vf produced in the heat generating layer 1a is expressed by the following equation (1).

$$\begin{matrix}Equation ( 1 ) & \\ {V}_{f} = - {N}_{c} \cdot \frac{Δ Φ 1}{Δ t} & ( 1 )\end{matrix}$$

$$Vf : INDUCED ELECTROMOTIVE FORCE \\ PRODUCED IN HEAT GENERATING LAYER 1 a$$

$$Nc : NUMBER OF TURNS OF EXCITING COIL 3$$

$$ΔΦ 1 / Δ t : CHANGE IN SHORT TIME PERIOD Δ t , \\ IN MAGNETIC FLUX THAT PASSES THROUGH \\ HEAT GENERATING LAYER 1 a PERPENDICULARLY$$

Thus, if the alternating current I1 (whose magnitude and direction change repeatedly with time) flows in the exciting coil 3 as illustrated in FIG. 5, the alternating magnetic field is formed in the magnetic core 2, the induced electromotive force Vf is applied to the whole (in the longitudinal direction) of the heat generating layer 1a in the circumferential direction, and a circumferential current I2 flows in the whole (in the longitudinal direction) of the heat generating layer 1a. The heat generating layer 1a has an electrical resistance. Thus, if the circumferential current I2 flows in the heat generating layer 1a, Joule heat is produced in the heat generating layer 1a. The circumferential current I2 is continuously generated while the direction of the circumferential current I2 is continuously changed, as long as the alternating magnetic field is continuously produced in the magnetic core. This is the principle of generating heat in the heat generating layer 1a in the configuration of the present embodiment. For example, if the current I1 is a high-frequency alternating current having a frequency of 60 kHz, the circumferential current I2 is also a high-frequency alternating current having a frequency of 60 KHz.

As illustrated in FIG. 4, the fixing apparatus 130 includes a temperature detection element 9 that serves as a temperature detection portion that detects the temperature of the fixing film 1. In the present embodiment, the temperature detection element 9 is disposed at a center portion of the fixing film 1 in the longitudinal direction, so as to be in contact with the inner surface of the fixing film 1 such that the temperature detection element 9 faces the upstream side in the conveyance direction of the recording material P. The CPU 32 includes a fixing-temperature control portion 44, a frequency control portion 45, an electric-power control portion 46, an engine control portion 43, and a detection-result comparison portion 49. The fixing-temperature control portion 44 receives the detection result from the above-described temperature detection element 9.

Based on the temperature of the fixing film 1 detected by the temperature detection element 9, the engine control portion 43 calculates the electric power applied (hereinafter, a word “supplied” may be used) for achieving a target temperature of the fixing film 1. The frequency control portion 45 outputs a control signal that represents the driving frequency of the high-frequency inverter 16, based on the electric power or the like calculated by the engine control portion 43. Depending on the control signal, the frequency control portion 45 can change the driving frequency of the high-frequency inverter 16. The electric-power control portion 46 outputs a control signal that represents the electric power of the high-frequency inverter 16, to the high-frequency inverter 16, based on the electric power or the like calculated by the engine control portion 43. More specifically, in the present embodiment, the high-frequency inverter 16 controls the amount of electric power applied to the fixing film 1, by using the PWM control. Thus, the electric-power control portion 46 outputs a control signal (e.g., a driving duty ratio) for the PWM control, a signal for changing an inverter circuit, and the like, to the high-frequency inverter 16. The high-frequency inverter 16 is driven, based on the temperature detected by the temperature detection element 9, by the control signal from the above-described frequency control portion 45 and electric-power control portion 46, so that the surface temperature of the fixing film 1 is kept at or adjusted into a predetermined target temperature.

### Detection Coil

Next, detection coils 5A, 5B, and 5C will be described. As illustrated in FIG. 4, the detection coils 5A, 5B, and 5C different from the exciting coil 3 are wound around the magnetic core 2 in a direction that intersects the axis X. The detection coils 5A, 5B, and 5C are magnetic-flux detection coils that detect the magnetic flux, and are disposed at a center portion and both end portions of the magnetic core 2. In the following description, the detection coil 5A is referred to also as a center-portion detection coil or a first detection coil. In addition, each of the detection coils 5B and 5C is referred to also as an end-portion detection coil or a second detection coil. Furthermore, the detection coil 5B, 5C disposed at a first end portion of the magnetic core 2 is referred to also as a first-end-portion detection coil, and the detection coil 5B, 5C disposed at a second end portion of the magnetic core 2 is referred to also as a second-end-portion detection coil. The detection coils 5A, 5B, and 5C may be disposed at a plurality of positions in the direction of the axis X of the magnetic core 2. However, the detection coil has only to be disposed at at least one position. For example, the detection coil may be disposed at only the center portion. Each of the detection coils 5A, 5B, and 5C has only to have a configuration in which the induced current flows in the detection coil when the alternating magnetic flux is produced from the magnetic core 2. Thus, the detection coil may not necessarily be wound around the magnetic core 2. For example, the detection coil may be spirally wound in the vicinity of the outside of the magnetic core 2.

In the present embodiment, the first detection coil 5A is disposed at a center position of the fixing film 1, the second detection coil 5B is disposed at a position separated by 15 mm from the left end of the fixing film 1, and a third detection coil 5C is disposed at a position separated by 15 mm from the right end of the fixing film 1. Each of the detection coils 5A, 5B, and 5C is wound, two turns, helically around the magnetic core 2 in a space between adjacent turns of the exciting coil 3. Since the detection coil is disposed in this manner, in a space between adjacent turns of the exciting coil 3, the detection coils 5A, 5B, and 5C can be disposed with the space saved, compared with detection coils wound around the magnetic core 2 so as to be put on the exciting coil 3. Note that although it may be that each of the detection coils 5A, 5B, and 5C be disposed in a space between adjacent turns of the exciting coil 3, the detection coil may be wound around the magnetic core 2 so as to be put on the exciting coil 3. The longitudinal length of the total of portions of the magnetic core 2 around which the detection coils 5A, 5B, and 5C may be wound is equal to or smaller than one third of the longitudinal length of the magnetic core 2.

One end of each of the detection coils 5A, 5B, and 5C is connected to the ground, and the other end of the detection coil is connected to a corresponding one of I-V conversion circuits 47a, 47b, and 47c. The output signal from each of the I-V conversion circuits 47a, 47b, and 47c is sent to the detection-result comparison portion 49 of the CPU 32.

If the alternating current flows in the exciting coil 3 and the alternating magnetic field is produced in the magnetic core 2, the electromagnetic induction occurs, and the induced current flows in each of the above-described detection coils 5A, 5B, and 5C. The I-V conversion circuits 47a, 47b, and 47c convert the induced currents, which flow in the above-described detection coils 5A, 5B, and 5C, to voltages. With this operation, the induced electromotive force produced in each of the detection coils 5A, 5B, and 5C can be detected. Like the heat generating layer 1a, an induced electromotive force Vd produced in each of the detection coils 5A, 5B, and 5C is expressed by the following equation (2).

$$\begin{matrix}Equation ( 2 ) & \\ {V}_{d} = - {N}_{d} \cdot \frac{Δ Φ 2}{Δ t} & ( 2 )\end{matrix}$$

$$Vd : INDUCED ELECTROMOTIVE FORCE \\ PRODUCED IN DETECTION COIL$$

$$Nc : NUMBER OF TURNS OF EXCITING COIL 3$$

$$Nd : NUMBER OF TURNS OF DETECTION COIL$$

$$ΔΦ 2 / Δ t : CHANGE IN SHORT TIME PERIOD Δ t , \\ IN MAGNETIC FLUX THAT PASSES THROUGH \\ THROUGH DETECTION COIL PERPENDICULARLY$$

In addition, since the magnetic flux that passes through each of the detection coils 5A, 5B, and 5C is substantially equal to the magnetic flux that passes through the heat generating layer 1a, the induced electromotive force Vd is expressed by the following equation (3), based on the expressions (1) and (2).

$$\begin{matrix}Equation ( 3 ) & \\ {V}_{d} = - \frac{{N}_{d}}{{N}_{c}} \cdot {V}_{f} & ( 3 )\end{matrix}$$

Thus, the induced electromotive force Vd produced in each of the detection coils 5A, 5B, and 5C is proportional to the induced electromotive force Vf produced in the heat generating layer 1a. That is, the amount of heat generation of the fixing film 1 can be calculated from the induced electromotive force Vd. Note that the conversion into the amount of heat generation of the fixing film 1 may be performed in each of the center portion and the end portion. That is, the voltage waveform of the induced electromotive force detected in the center portion by a corresponding one of the detection coils 5A, 5B, and 5C is different from the voltage waveform of the induced electromotive force detected in the end portion by a corresponding one of the detection coils 5A, 5B, and 5C. Specifically, since the center portion has a large L (inductance) component, the square wave has a rounded integrated waveform. In contrast, since the end portion has a small L component, the square wave has a differentiated waveform having overshoot. Thus, in a case where an average or effective value of the voltage waveform is determined, the correction coefficient for the center portion and the correction coefficient for the end portion may be made different from each other.

### Frequency Dependence of Temperature Distribution of Fixing Film

Next, the frequency dependence of the temperature distribution of the fixing film 1 will be described. In a case where most of the magnetic flux from one end portion of the magnetic core 2 returns to the other end portion of the magnetic core 2 through the space outside the heat generating layer 1a so that the induced current flows in the heat generating layer (conductive layer) 1a in the circumferential direction of the fixing film 1, the longitudinal temperature distribution of the fixing film 1 changes in accordance with the frequency of the induced current.

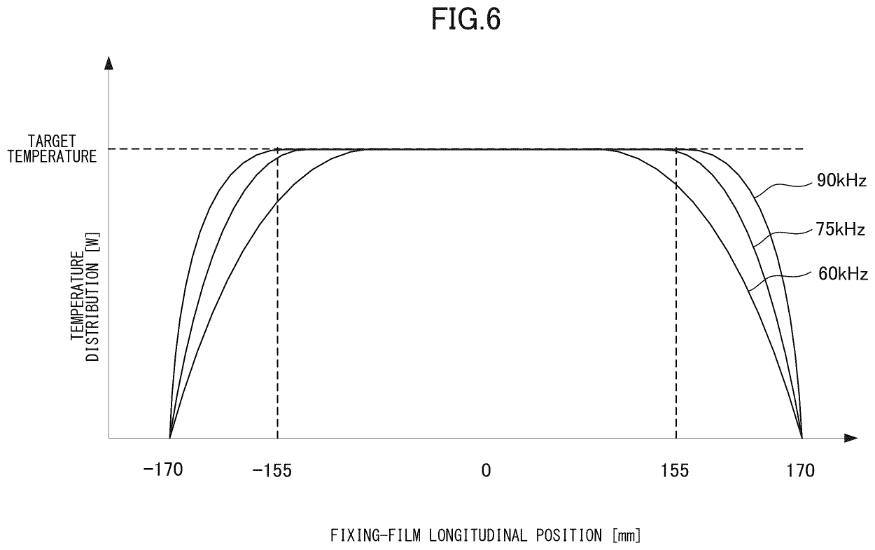

FIG. 6 is a graph illustrating a longitudinal temperature distribution of the fixing film 1 in which the driving frequency of the high-frequency inverter 16 was changed. The temperature of both ends of the fixing film 1 decreases as the driving frequency of the high-frequency inverter 16, that is, the frequency of the induced current that flows in the circumferential direction of the fixing film 1 is decreased. By using this feature, in the fixing apparatus 130 of the present embodiment, the driving frequency is changed in accordance with the size of the recording material P and the temperature of a non-sheet passing area of the fixing film 1. Note that the non-sheet passing area is an area which a recording material having the maximum size used for the image forming apparatus 100 passes, but which a recording material having a size smaller than the maximum size does not pass. In a case where the fixing process is performed on a recording material having the maximum size, the control is performed so that the whole of the fixing film 1 in the longitudinal direction generates heat uniformly. In contrast, in a case where the fixing process is performed on a recording material having a smaller size, the control is performed so that the temperature of the end portions of the fixing film 1 is lowered by decreasing the driving frequency. In this manner, in a case where the fixing process is performed on a recording material having a smaller size, the temperature rise of the non-sheet passing area can be suppressed and the energy can be saved.

Relationship between Induced Electromotive Force of Detection Coil and Electric Power Supplied to Exciting Coil

Next, the influence of the driving frequency of the high-frequency inverter 16 to the relationship between the electric power supplied to the exciting coil 3 and the voltage detected by the detection coil will be described. As described above, if the electric power is supplied from the high-frequency inverter 16 to the exciting coil 3, the alternating current flows in the exciting coil 3, and the voltage (i.e., the induced electromotive force Vd) that corresponds to the electric power supplied (applied) to the exciting coil 3 occurs in the detection coil 5A. Note that the electric power supplied to the exciting coil 3 is determined by the control signal sent from the CPU 32 to the high-frequency inverter 16. For example, the electric power is set at 1000 W when the printing is started, and is set at 500 W when the continuous printing is performed. In addition, the amount of supplied electric power (i.e., the amount of applied electric power) is determined, based on the driving duty ratio, the driving frequency, and the alternating-current voltage.

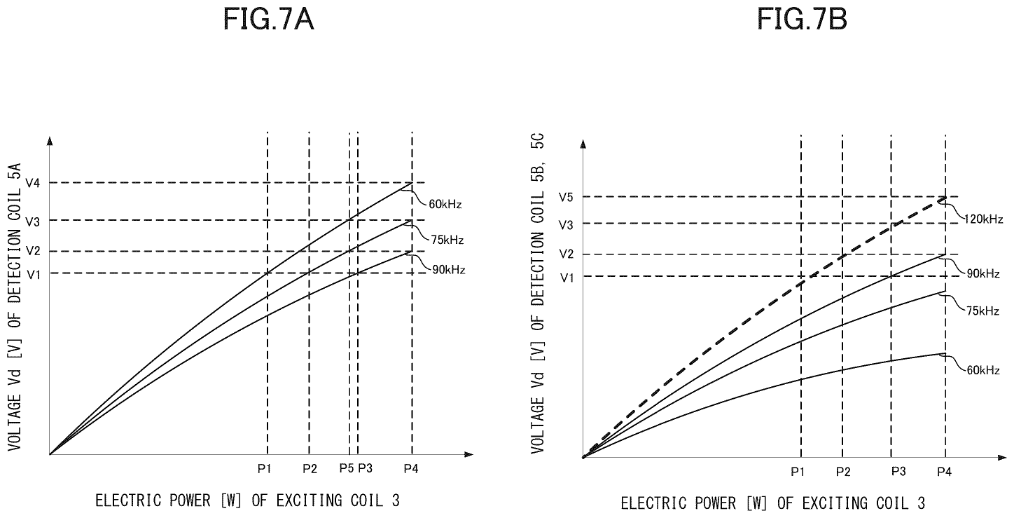

FIG. 7A is a graph illustrating a relationship between the electric power supplied to the exciting coil 3 and the voltage produced in the detection coil 5A. In FIG. 7A, the driving frequency of the high-frequency inverter 16 was changed and set at 60 kHz, 75 kHz, and 90 kHz. Note that in FIG. 7A, a voltage V1 is a voltage detected by the detection coil 5A in a case where the amount of heat necessary for achieving a predetermined target surface temperature of the center portion of the fixing film 1 was generated.

As can be seen from the graph of FIG. 7A, the electric power supplied to the whole of the exciting coil 3 in a case where the voltage detected by the detection coil 5A is V1 increases as the driving frequency of the high-frequency inverter 16 increases. That is, an electric power P2 supplied when the voltage detected by the detection coil 5A is V1 in a case where the driving frequency is 75 kHz is greater than an electric power P1 supplied when the voltage detected by the detection coil 5A is V1 in a case where the driving frequency is 60 kHz. In addition, an electric power P3 supplied when the voltage detected by the detection coil 5A is V1 in a case where the driving frequency is 90 KHz is greater than the electric power P2 supplied when the voltage detected by the detection coil 5A is V1 in a case where the driving frequency is 75 kHz (P1<P2<P3).

This is because, as described with reference to FIG. 6, the temperature distribution of the fixing film 1 in the longitudinal direction changes in accordance with the driving frequency of the high-frequency inverter 16, and the temperature of both end portions of the fixing film 1 increases as the driving frequency increases. That is, as the driving frequency increases, the surface temperature of the end portions obtained when the surface temperature of the center portion of the fixing film 1 reaches a target temperature increases. For increasing the temperature of the end portions of the fixing film 1, higher energy is required. Thus, even if the surface temperature of the center portion is the target temperature in all cases, the electric power supplied to the exciting coil 3 increases as the driving frequency increases. On the other hand, if the electric power supplied to the exciting coil 3 is constant, the surface temperature of the center portion of the fixing film 1 increases as the driving frequency of the high-frequency inverter 16 decreases.

### Control of Electric Power Supplied to Exciting Coil

By the way, if an error occurs in the temperature detection element 9, the control portion 31 may erroneously detect a value less than an actual value. In this case, if the control portion 31 controls the electric power for continuously increasing the temperature, the temperature of the fixing film 1 may exceed the target temperature and reach an abnormal temperature. As countermeasures, for preventing the excessive electric power from being applied to the fixing film 1, the electric power supplied to the exciting coil 3 could be limited to a value equal to or lower than a predetermined value.

Specifically, if the electric-power usage range in the normal operation of the exciting coil 3 is P1 to P3 in FIG. 7A, the limited electric power for the case where an error occurs in the temperature detection element 9 could be set at P4 greater than the electric power P1 to P3.

However, as described above, even if the limited electric power P4 is supplied to the fixing film 1, the amount of heat generation of the center portion of the fixing film 1 increases as the driving frequency of the high-frequency inverter 16 decreases. This is because as the driving frequency of the high-frequency inverter 16 decreases, the electric power consumed in the end portions of the fixing film 1 decreases. That is, since the electric power for the exciting coil 3 is supplied to the center portion of the fixing film 1 in a collective manner, the amount of heat generation of the center portion of the fixing film 1 increases.

For example, in FIG. 7A, the voltage detected by the detection coil 5A is V2 in a case where the driving frequency is 90 kHz, whereas the voltage detected by the detection coil 5A is V3 greater than V2 in a case where the driving frequency is 75 kHz. In addition, the voltage detected by the detection coil 5A is V4 greater than V3 in a case where the driving frequency is 60 KHz. The induced electromotive force (detection voltage) Vd produced in the detection coil 5A is proportional to the induced electromotive force Vf produced in the heat generating layer 1a of the center portion of the fixing film 1, that is, is proportional to the amount of heat generation of the center portion of the fixing film 1. Thus, as the above-described detection voltage increases, the amount of heat generation of the center portion of the fixing film 1 increases.

As described above, even if the electric power supplied to the exciting coil 3 is limited to the predetermined value P4, the amount of heat generation (i.e., the temperature) of the center portion of the fixing film 1 varies in accordance with the driving frequency of the high-frequency inverter 16. For example, the voltage detected by the detection coil 5A in a case where the maximum allowable amount of heat is generated is denoted by V3. The maximum allowable amount of heat corresponds to the maximum value of a temperature range in which the temperature of the fixing film 1 does not damage the apparatus. In this case, the voltage detected by the detection coil 5A is equal to or lower than V3 in a case where the driving frequency is one of the 90 KHz and 75 kHz. However, in a case where the driving frequency is 60 kHz, the voltage detected by the detection coil 5A is V4 greater than V3. That is, the amount of heat generated by the center portion of the fixing film 1 is greater than the maximum allowable amount of heat generation.

On the other hand, if the amount of heat generated by the center portion of the fixing film 1 in a case where the driving frequency of the high-frequency inverter 16 is 60 kHz is limited so as not to exceed the maximum allowable amount of heat generation, that is, if the voltage detected by the detection coil 5A is limited so as not to exceed V3, it is necessary to limit the electric power supplied to the exciting coil 3 to a value equal to or lower than P5. However, as can be seen from FIG. 7A, the electric power P5 supplied to the exciting coil 3 is lower than the electric power P3 (P5<P3) supplied normally in a case where the driving frequency of the high-frequency inverter 16 is 90 KHz. Thus, in this case, it is necessary to narrow the electric-power usage range of the exciting coil 3 in the normal operation. As a result, the required electric power becomes insufficient, so that the print speed will decrease, for example.

In another case, an error may occur not in the temperature detection element 9, but in the frequency control portion 45. In this case, the high-frequency inverter 16 may have a failure, and may be driven at a frequency higher than the driving frequency that was set. If the driving frequency of the high-frequency inverter 16 increases, the temperature of the end portions of the fixing film 1 increases.

FIG. 7B is a graph illustrating a relationship between the electric power supplied to the exciting coil 3 and the voltage detected by the detection coil 5B, 5C. In FIG. 7B, the driving frequency of the high-frequency inverter 16 was changed. For example, in the example of FIG. 7B, in a case where the high-frequency inverter 16 operates in a normal range of the driving frequency, the highest driving frequency is 90 KHz.

If the electric power supplied to the exciting coil 3 is limited to a predetermined value P4 in a case where the driving frequency is 90 kHz, the voltage detected by the detection coil 5B, 5C is V2. As can be seen from temperature distribution of FIG. 6, in a case where the driving frequency is 90 kHz, the relationship between the amount of heat generation of the end portion of the fixing film 1 and the detection voltage is the same as the relationship obtained by using the detection coil 5A. In a case where the driving frequency is equal to or lower than 90 kHz, if the electric power supplied to the exciting coil 3 is limited to a value equal to or lower than P4, the amount of heat generation of the end portion of the fixing film 1 does not exceed the maximum allowable amount of heat generation because the above-described detection voltage V2 is lower than the detection voltage V3.

However, there may be a case where the high-frequency inverter 16 is in a state where the energization is out of control, and is operated at a frequency equal to or higher than the maximum driving frequency. For example, if the high-frequency inverter 16 is operated at 120 kHz indicated by a dotted line in FIG. 7B, the voltage detected by the detection coil 5B, 5C becomes higher than V3. More specifically, if the high-frequency inverter 16 is driven at a driving frequency of 120 kHz, and the electric power supplied to the exciting coil 3 is P4, the voltage detected by the detection coil 5B, 5C is V5 higher than V3. Thus, in a case where the high-frequency inverter 16 is driven at a frequency equal to or higher than the maximum driving frequency, even if the electric power supplied to the exciting coil 3 is limited to a predetermined value, the end portion of the fixing film 1 may excessively generate heat, depending on a frequency at which the high-frequency inverter 16 is actually driven.

### Limiting Heat Generation of Fixing Film by Induced Electromotive Force of Detection Coil

Thus, in the present embodiment, for solving the above-described problem, not the electric power supplied to the exciting coil 3, but the induced electromotive force Vd produced in each of the detection coils 5A, 5B, and 5C disposed for the corresponding portions (formed in the longitudinal direction) of the fixing film 1 is limited to a value equal to or lower than a predetermined value. For example, the induced electromotive force Vd produced in each of the detection coils 5A, 5B, and 5C is limited so as to have a value equal to or lower than the predetermined value V3. As a result, the amount of heat generation of each portion (formed in the longitudinal direction) of the fixing film 1 can be limited to a value equal to or less than the maximum allowable amount of heat generation, regardless of the driving frequency of the high-frequency inverter 16.

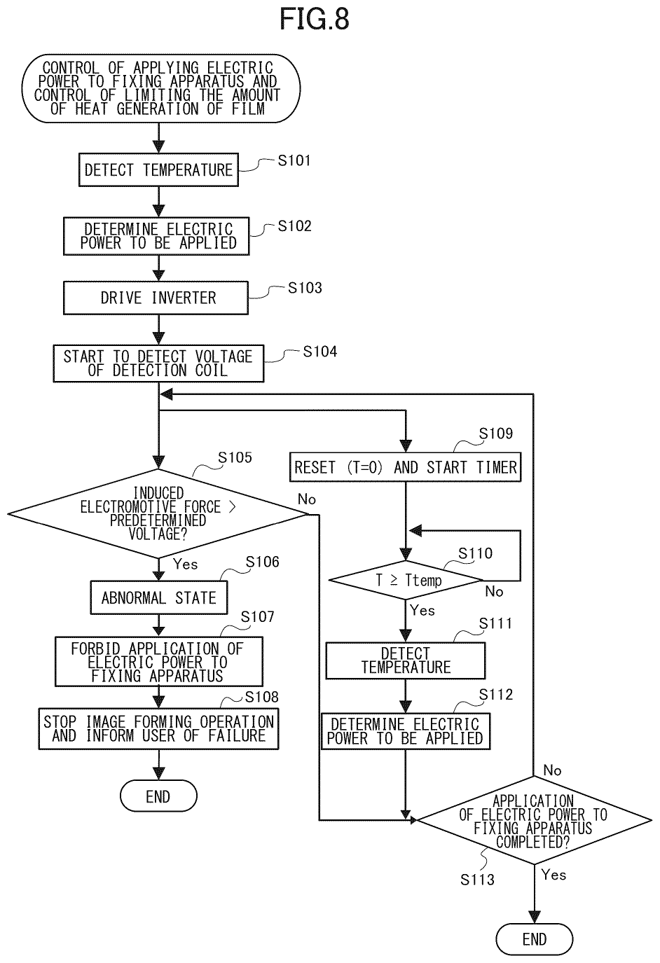

Hereinafter, with reference to a flowchart of FIG. 8, the control of limiting the amount of heat generation of the fixing film 1 of the present embodiment will be described, together with a driving sequence of the fixing apparatus 130. Note that the control process illustrated in the flowchart is executed, depending on a program stored in advance in a storage portion (e.g., the ROM 32a) of the CPU 32.

For causing the fixing film 1 to generate heat, the CPU 32 detects a current temperature, based on a detection result from the temperature detection element 9 (Step S101 in FIG. 8). Then the CPU 32 determines the electric power applied to the exciting coil 3, based on the difference between a target temperature of the fixing film 1 and the current temperature (S102), and supplies the electric power to the exciting coil 3 by driving the high-frequency inverter 16 (S103). At the same time, the CPU 32 starts to detect the induced electromotive force Vd produced in each of the detection coils 5A, 5B, and 5C, by causing the I-V conversion circuits 47a, 47b, and 47c to convert the induced current that flows in the respective detection coils 5A, 5B, and 5C, to corresponding voltages (S104).

The CPU 32 functions as the detection-result comparison portion 49, and determines whether the induced electromotive force Vd of each detection coil, converted by a corresponding one of the I-V conversion circuits 47a, 47b, and 47c, exceeds the predetermined voltage V3 (S105). If the induced electromotive force Vd of at least one of the detection coils 5A, 5B, and 5C has exceeded the predetermined voltage V3 (S105: Yes), then the CPU 32 determines that the fixing film 1 is generating heat abnormally (S106). In this case, the CPU 32 forbids the supply of electric power to the fixing apparatus (S107). In addition, the CPU 32 urgently stops the image forming operation, and informs a user of the error via an operation panel (not illustrated) or the like (S108).

If the induced electromotive force Vd of each of the detection coils 5A, 5B, and 5C is equal to or lower than the predetermined voltage V3, then the CPU 32 determines the state of the fixing film, as a normal state (S105: No). In addition, the CPU 32 continues the image forming operation, and monitors the induced electromotive force Vd of each of the detection coils 5A, 5B, and 5C, converted by a corresponding one of the I-V conversion circuits 47a, 47b, and 47c.

After Step S104, in parallel with the operations after Step S105, the CPU 32 resets and starts a timer T (S109). Then the CPU 32 waits until a predetermined time Ttemp has elapsed, for detecting a current temperature for determining the next electric power to be supplied (S110: No). If the time Ttemp has elapsed (S110: Yes), then the CPU 32 determines the next electric power applied for the energization, as in the previous determination, based on the detected-temperature information (S111 to S112). If the electric power is to be applied continuously (S113: No), then the CPU 32 returns to the steps S105 and S109, and repeats the above-described control.

If the CPU 32 determines, in Step S113, to end the supply of electric power to the fixing apparatus 130 (S113: Yes), then the CPU 32 ends the control of applying electric power to the fixing apparatus. Note that the end of applying the electric power to the fixing apparatus 130 is to forbid the application of the fixing electric power due to the completion of printing or a factor of the emergency stop, such as a jam or an error, in the image forming apparatus 100.

In the above-described control of limiting the amount of heat generation of the film, the CPU 32 forbids the application of electric power to the fixing apparatus in a case where the CPU 32 determines that the fixing film 1 is generating heat abnormally. In this case, however, the CPU 32 may limit the electric power applied to the fixing apparatus, so that the induced electromotive force becomes equal to or lower than the predetermined voltage V3, by limiting the driving duty ratio of the high-frequency inverter 16. For example, the CPU 32 may perform the control such that the driving duty ratio of the high-frequency inverter 16 is decreased. In another case, in consideration of noise or instantaneous application of electric power in the startup, the CPU 32 may determine that the fixing film 1 is generating heat abnormally, only in a case where the induced electromotive force Vd exceeds the predetermined voltage V3 continuously in a predetermined period of time.

The detection coil 5B on one end portion of the fixing film 1 is disposed at a position separated by 15 mm from the left end portion of the fixing film 1, and the detection coil 5C on the other end portion of the fixing film 1 is disposed at a position separated by 15 mm from the right end portion of the fixing film 1. However, the distance between the position of the detection coil 5B and the left end portion of the fixing film 1 and the distance between the position of the detection coil 5C and the right end portion of the fixing film 1 may be different from each other. For example, the detection coil 5B may be disposed at a position separated by 15 mm from the left end portion of the fixing film 1, and the detection coil 5C may be disposed at a position separated by 30 mm from the right end portion of the fixing film 1. In addition, the number of turns of one of the detection coils 5A, 5B, and 5C may be different from the number of turns of another. Similarly, the predetermined value V3 for limiting the amount of heat generation of the fixing film 1 may be a predetermined value that varies in accordance with the induced electromotive force detected by each detection coil.

In addition, in the above-described embodiment, in a case where the induced electromotive force Vd of any one of the detection coils 5A, 5B, and 5C exceeds the predetermined voltage V3, the CPU 32 determines the state of the fixing film, as an abnormal state. However, the detection coil may be disposed at at least one position in the longitudinal direction of the magnetic core 2, and the CPU 32 may determine that the fixing film 1 is generating heat abnormally if the voltage detected by the detection coil exceeds a predetermined voltage.

As described above, in the present embodiment, the detection coils 5A, 5B, and 5C are disposed for detecting the amount of heat generation of each portion (formed in the longitudinal direction) of the fixing film 1, and the CPU 32 limits the induced electromotive force Vd detected by each of the detection coils 5A, 5B, and 5C so that the electromotive force Vd has a value equal to or lower than a predetermined value. Specifically, in a case where the induced electromotive force Vd detected by each of the detection coils 5A, 5B, and 5C exceeds the predetermined value, the CPU 32 stops or reduces the electric power supplied from the high-frequency inverter 16 to the exciting coil 3. With this operation, in a case where the energization is out of control, the amount of heat generation of each portion (formed in the longitudinal direction) of the fixing film 1 can be limited so as to have a value equal to or lower than the maximum allowable amount of heat generation, regardless of the driving frequency of the high-frequency inverter 16, without changing the electric-power usage range of the exciting coil 3 used in the normal operation.

### Adjustment of Longitudinal Temperature Distribution

In the present embodiment, the induced electromotive force Vd produced in each of the detection coils 5A, 5B, and 5C is used not only for the control of limiting the amount of heat generation of the fixing film, but also for adjusting the longitudinal temperature distribution of the fixing film 1. As described with reference to FIG. 6, the longitudinal temperature distribution of the fixing film 1 can be adjusted by changing the driving frequency of the high-frequency inverter 16.

The fixing apparatus 130 is set in advance so that the temperature of each portion (formed in the longitudinal direction) of the fixing film 1 has a desired temperature for each driving frequency of the high-frequency inverter 16 in consideration of characteristics, such as the number of turns of the exciting coil 3, the interval of turns of the exciting coil 3, and the relative permeability of the magnetic core 2. However, due to variations in characteristics, such as the tolerance of a winding position involved with the assembly of the exciting coil 3 and the relative permeability of the magnetic core 2, the induced electromotive force produced in each portion (formed in the longitudinal direction) of the fixing film 1 may have a value different from a value estimated in advance. As a result, the longitudinal temperature distribution of the fixing film 1 may be different from a desired temperature distribution.

In the present embodiment, based on the induced electromotive force Vd produced in each of the detection coils 5A, 5B, and 5C, the CPU 32 determines whether the induced electromotive force Vd produced in each of the center portion, the left end portion, and the right end portion of the fixing film 1 has a desired value for each driving frequency of the high-frequency inverter 16. If the induced electromotive force Vd produced in each of the detection coils 5A, 5B, and 5C does not have a desire value, the CPU 32 adjusts the longitudinal temperature distribution of the fixing film 1 into the desired temperature distribution by correcting the driving frequency of the high-frequency inverter 16 so that the induced electromotive force Vd produced in each of the detection coils 5A, 5B, and 5C has the desired value.

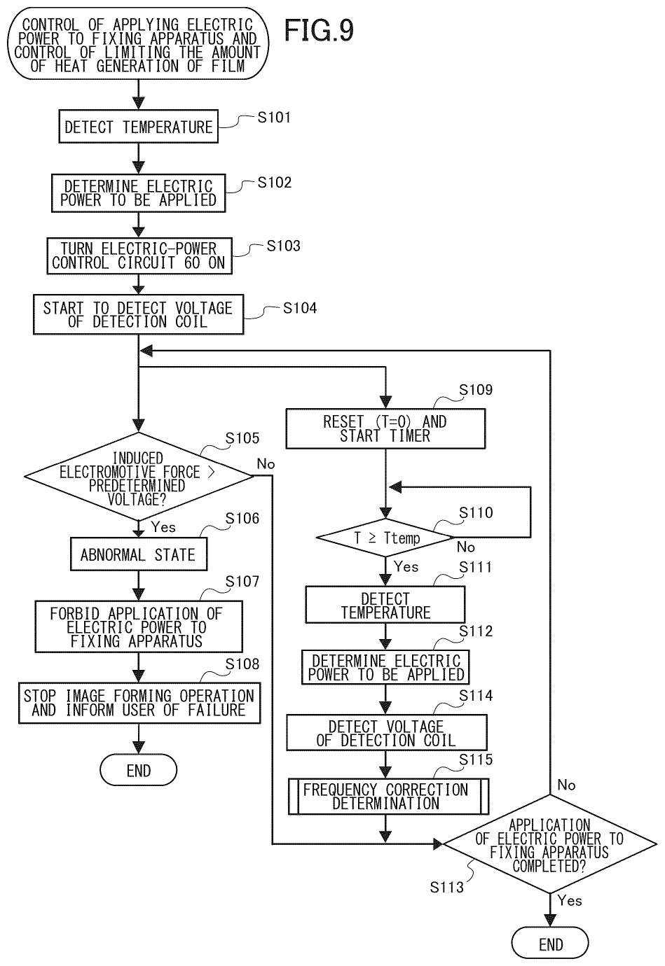

Next, the control of correcting the driving frequency of the high-frequency inverter 16 in the present modification will be specifically described with reference to a flowchart of FIG. 9. In FIG. 9, since the steps S101 to S113 are the same as the steps S101 to S113 of FIG. 8, the description thereof will be omitted. After determining, in Step S112, the next electric power applied for the energization, the CPU 32 detects the induced electromotive force Vd of each of the detection coils 5A, 5B, and 5C, converted by a corresponding one of the I-V conversion circuits 47a, 47b, and 47c (S114). Then the CPU 32 starts the frequency correction determination for determining whether to change the driving frequency of the high-frequency inverter 16, based on the induced electromotive force of each of the detection coils 5A, 5B, and 5C detected by the CPU 32 (S115).

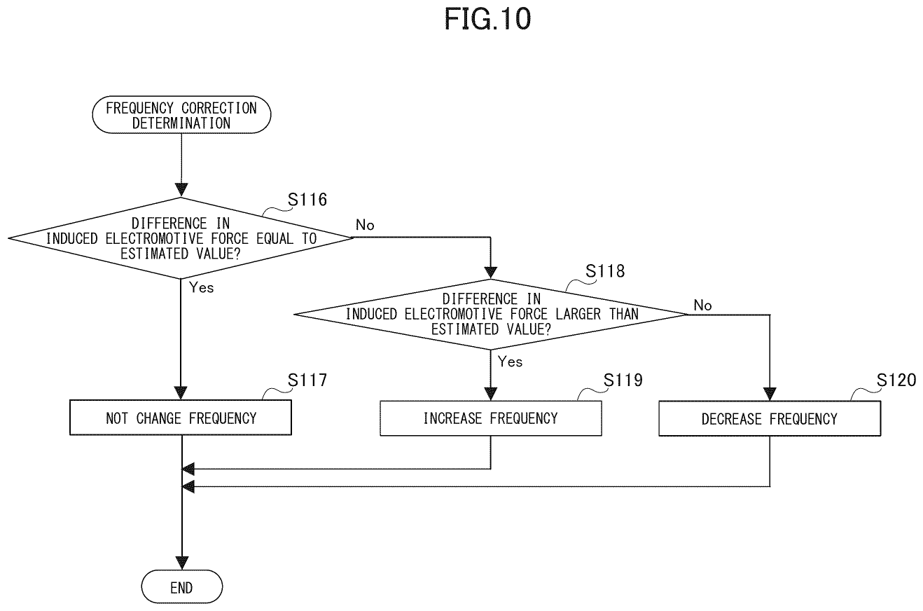

Next, the frequency-correction determination process will be described with reference to FIG. 10. As described with reference to FIG. 6, in a case where the driving frequency of the high-frequency inverter 16 is 90 kHz, the target temperature of a portion of the fixing film 1 in which the center-portion detection coil 5A is disposed is equal to the target temperature of a portion of the fixing film 1 in which the end-portion detection coil 5B, 5C is disposed. Thus, the amount of heat generation detected by the center-portion detection coil 5A is substantially equal to the amount of heat generation detected by the end-portion detection coil 5B, 5C. That is, the induced electromotive force of the center-portion detection coil 5A is substantially equal to the induced electromotive force of the end-portion detection coil 5B, 5C. However, as the driving frequency of the high-frequency inverter 16 decreases, the target temperature of the end portion of the fixing film 1 decreases. Thus, the induced electromotive force of the end-portion detection coil 5B, 5C also decreases. Thus, as the driving frequency of the high-frequency inverter 16 decreases, the difference between the induced electromotive force of the center-portion detection coil 5A and the induced electromotive force of the end-portion detection coil 5B, 5C increases. In the present embodiment, an estimated difference between the induced electromotive force of the center-portion detection coil 5A and the induced electromotive force of the end-portion detection coil 5B, 5C is set in advance, as a predetermined value, in the CPU 32 for each driving frequency of the high-frequency inverter 16.

In the frequency-correction determination process, the CPU 32 compares the estimated value of the difference in the induced electromotive force that corresponds to the current driving frequency of the high-frequency inverter 16, and the actual value of the difference in the induced electromotive force (S116). That is, the CPU 32 compares the above-described estimated value and the actual value of the difference, detected in S114, between the induced electromotive force of the center-portion detection coil 5A and the induced electromotive force of the end-portion detection coil 5B, 5C. If the difference in the induced electromotive force is substantially equal to the predetermined estimated value (that is, the difference is in a predetermined range), the CPU 32 determines that the fixing film 1 is generating an expected amount of heat based on the induced electromotive force. In this case, the CPU 32 does not change the driving frequency of the high-frequency inverter 16 (S117), and ends the frequency-correction determination process.

If the difference in the induced electromotive force is different from the predetermined estimated value, the CPU 32 determines whether the difference in the induced electromotive force is greater than the predetermined estimated value (S118). If the difference in the induced electromotive force is greater than the predetermined estimated value, the CPU 32 determines that the difference between the temperature of the center portion of the fixing film 1 and the temperature of the end portion of the fixing film 1 is greater than an estimated value. In this case, the CPU 32 decreases the difference in the temperature by increasing the amount of heat generation of the end portion, by increasing the driving frequency of the high-frequency inverter 16 (S119). After that, the CPU 32 ends the frequency-correction determination process.

In contrast, if the difference in the induced electromotive force is less than the predetermined estimated value, the CPU 32 determines that the difference between the temperature of the center portion of the fixing film 1 and the temperature of the end portion of the fixing film 1 is less than the estimated value. In this case, the CPU 32 increases the difference in the temperature by decreasing the amount of heat generation of the end portion, by decreasing the driving frequency of the high-frequency inverter 16 (S120). After that, the CPU 32 ends the frequency-correction determination process. The steps for changing the frequency may be predetermined fixed steps, or may be determined in accordance with the difference between the estimated induced electromotive force of the end-portion detection coil 5B, 5C and the actual induced electromotive force detected by the end-portion detection coil 5B, 5C.

By correcting the driving frequency, as described above, based on the induced electromotive force Vd produced in the detection coils 5A, 5B, and 5C, the fixing film 1 can have desired longitudinal temperature distribution even if the variations in characteristics, such as the tolerance of a winding position involved with the assembly of the exciting coil 3 and the relative permeability of the magnetic core 2, occur. Note that the above-described estimated value is obtained by adding the difference between the induced electromotive force of the center portion and the induced electromotive force of the end portion, with an allowable value. The difference is obtained experimentally by driving the high-frequency inverter 16 with a predetermined frequency and driving duty ratio, or is calculated theoretically. The driving frequency may be corrected by using the induced electromotive force of each of the detection coils 5A, 5B, and 5C, independently. However, if the driving frequency is corrected, based on the difference between the induced electromotive force of the center-portion detection coil 5A and the induced electromotive force of the end-portion detection coil 5B, 5C, the driving frequency can be more effectively corrected. For example, in a case where the printing is performed continuously, the induced electromotive force decreases with time as components around the fixing film are gradually warmed. In this case, if the induced electromotive force of each of the detection coils 5A, 5B, and 5C is used independently, it is difficult to determine whether the change in the induced electromotive force is simply caused by the temperature rise or needs the correction of the driving frequency. However, in the present embodiment in which the difference between the induced electromotive force of the center-portion detection coil 5A and the induced electromotive force of the end-portion detection coil 5B, 5C is detected, the difference between the center portion and the end portion (the difference corresponds to the difference in the temperature distribution of the fixing film in the longitudinal direction) can be timely and effectively detected. In addition, by adjusting the driving frequency based on the difference in the induced electromotive force, the driving frequency can be adjusted so that the heat generation distribution becomes more uniform.

In the above-described embodiment, the driving frequency of the high-frequency inverter is corrected based on the induced electromotive force detected by the detection coils 5A, 5B, and 5C. However, temperature detection elements may be disposed at the center portion and the end portion of the fixing film 1. In this case, the above-described driving frequency may be corrected if the difference between the temperature of the center portion of the fixing film 1 detected by one of the temperature detection elements and the temperature of the end portion of the fixing film 1 detected by another of the temperature detection elements is greater than a predetermined difference. That is, the detection coils 5A, 5B, and 5C and the temperature detection elements are heat-generation-amount detection portions that detect the amount of heat generation of the center portion of the fixing film and the amount of heat generation of the end portion of the fixing film. In addition, the difference between the amount of heat generation of the center portion of the fixing film 1 and the amount of heat generation of the end portion of the fixing film 1 is determined, based on the detection result from a first heat-generation-amount detection portion that detects the amount of heat generation of the center portion of the fixing film 1 and the detection result from a second heat-generation-amount detection portion that detects the amount of heat generation of the end portion of the fixing film 1. Thus, the driving frequency of the high-frequency inverter 16 is corrected if the difference in the amount of heat generation is greater than an estimated value.

### Second Embodiment

Next, a second embodiment will be described. The second embodiment differs from the first embodiment in the control of limiting the amount of heat generation of the film. Thus, in the following description, the description will be made for only the features different from those of the first embodiment, and the features identical to those of the first embodiment will not be described, and are given symbols identical to those of the first embodiment.

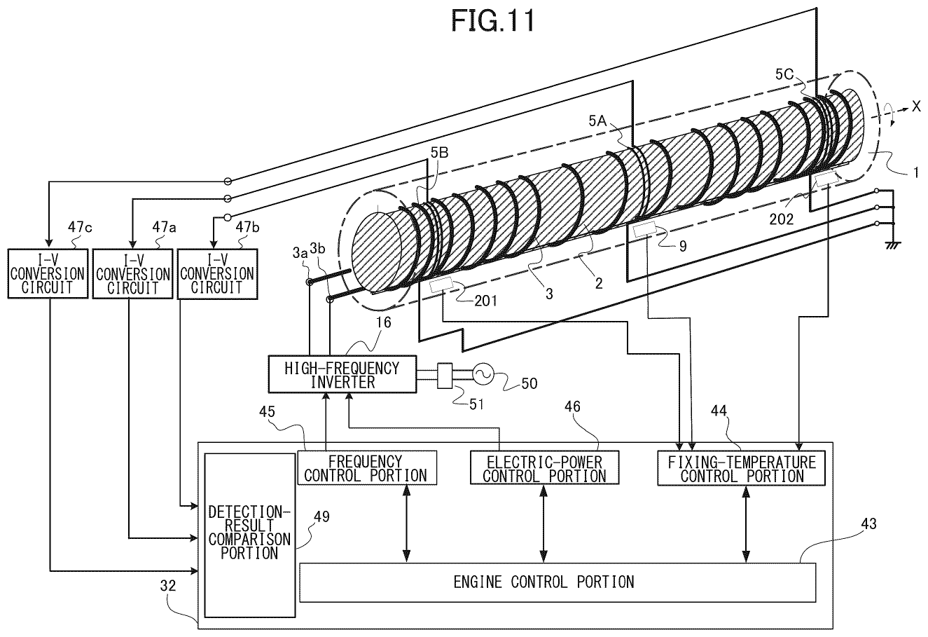

FIG. 11 is a perspective view of the fixing film 1 of the second embodiment, and is a diagram illustrating a configuration of circuits to which the fixing film 1 is connected. In the present embodiment, the fixing apparatus 130 includes, in addition to the temperature detection element 9 disposed at a center portion of the fixing film 1, a temperature detection element 201 disposed at a left end portion of the fixing film 1 and a temperature detection element 202 disposed at a right end portion of the fixing film 1. The temperature detection element 201 at the left end portion is disposed at a position separated by 15 mm from the left end portion, and the temperature detection element 202 at the right end portion is disposed at a position separated by 15 mm from the right end portion. In addition, like the temperature detection element 9, each of the temperature detection elements 201 and 202 is disposed so as to be in contact with the inner surface of the fixing film 1 such that the temperature detection element faces the upstream side in the conveyance direction of the recording material P.

Each of the temperature detection elements 9, 201, and 202 is connected to the fixing-temperature control portion 44 disposed in the CPU 32. The engine control portion 43 of the CPU 32 calculates the electric power applied to the fixing film 1 and the driving frequency, based on signals from the temperature detection elements 9, 201, and 202, and on signals from the I-V conversion circuits 47a, 47b, and 47c that convert induced currents produced in the detection coils, to voltages. In addition, the engine control portion 43 drives the high-frequency inverter 16 with the calculated electric power and frequency, via control signals outputted from the frequency control portion 45 and the electric-power control portion 46; and thereby keeps/adjusts the surface temperature of each portion (formed in the longitudinal direction) of the fixing film 1, at/into a target temperature.

### Determination of Abnormal Amount of Temperature Rise

As described above, in the present embodiment, the temperature detection elements 9, 201, and 202 are disposed in the longitudinal direction, at positions corresponding to the detection coils 5A, 5B, and 5C. In this arrangement, the temperature and the induced electromotive force of the fixing film 1 can be detected at each of the positions (i.e., the center portion and both end portions) of the fixing film 1 at which the above-described detection coils 5A, 5B, and 5C and temperature detection elements 9, 201, and 202 are disposed. In the present embodiment, the temperature of each portion of the fixing film 1 and a corresponding induced electromotive force are detected and compared with each other, so that whether the amount of temperature rise is abnormal can be determined.

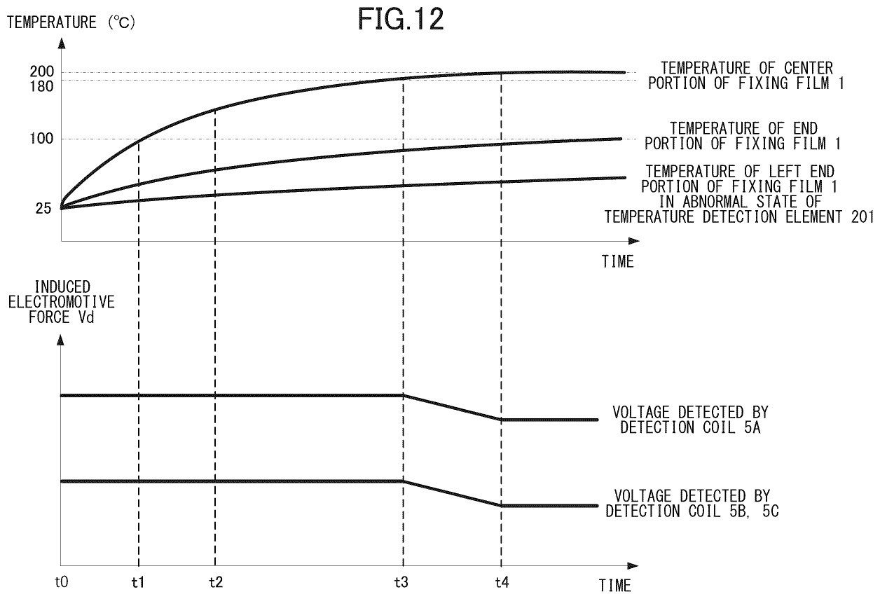

FIG. 12 is a graph illustrating a relationship between the temperature of the fixing film 1 and the voltage detected by each of the detection coils 5A, 5B, and 5C in a case where the driving of the high-frequency inverter 16 is started with a driving frequency of 60 KHz. Note that the driving frequency of 60 kHz is used, for example, for fixing an image to a small-size recording material. In the example of FIG. 12, the target temperature of the center portion of the fixing film 1 is 200° C., and the target temperature of the end portion of the fixing film 1 is 100° C.

If the high-frequency inverter 16 starts the driving (at a time to in FIG. 12) and the electric power is applied to the exciting coil 3, the temperature of the fixing film 1 starts to rise toward the target temperature. In a case where the driving frequency is 60 kHz, the amount of heat generation of the end portion of the fixing film 1 is less than the amount of heat generation of the center portion of the fixing film 1. Thus, in a period of time, for example, from the time t0 to a time t3, the temperature of the end portion of the fixing film 1 rises more gently than the temperature of the center portion of the fixing film 1 does. In addition, the induced electromotive force produced in the end portion of the fixing film 1 is less than the induced electromotive force Vd produced in the center portion of the fixing film 1.

Furthermore, when the temperature of the center portion of the fixing film 1 detected by the temperature detection element 9 reaches 180° C. at the time t3 in FIG. 12, the CPU 32 adjusts the electric power applied to the exciting coil 3, and thereby decreases the electric power for preventing the overshoot of the temperature of the fixing film 1. If the electric power applied to the exciting coil 3 is decreased, the induced electromotive force Vd detected by each of the detection coils 5A, 5B, and 5C also decreases accordingly.

In addition, when the temperature of the center portion of the fixing film 1 detected by the temperature detection element 9 reaches the target temperature of 200° C. at a time t4, the CPU 32 drives the high-frequency inverter 16 with the electric power, applied to the exciting coil 3, necessary for keeping the temperature of the center portion of the fixing film 1 at the target temperature. Thus, the induced electromotive force Vd detected by each of the detection coils 5A, 5B, and 5C has a magnitude that corresponds to the electric power applied to the exciting coil 3.

By the way, there may be a case where an error occurs in the temperature detection element 201 disposed at the left end portion of the fixing film 1 and the inner-surface temperature of the left end portion of the fixing film 1 cannot be detected correctly. In this case, as illustrated in FIG. 12, the control portion 31 erroneously detects an inner-surface temperature of the left end portion of the fixing film 1 that is lower than the actual temperature. On the other hand, the induced electromotive force Vd detected by the left-end-portion detection coil 5B is proportional to the driving frequency and the electric power applied to the exciting coil 3, regardless of the state of the temperature detection element 201.

As described in the first embodiment, even if the amount of electric power applied to the exciting coil 3 is constant, the amount of temperature rise of each portion (formed in the longitudinal direction) of the fixing film 1 varies in accordance with the driving frequency of the high-frequency inverter 16. Thus, it is not possible to calculate the amount of temperature rise of each portion (formed in the longitudinal direction) of the fixing film 1 by using the amount of electric power. However, if the induced electromotive force Vd detected by each of the detection coils 5A, 5B, and 5C can be obtained, it is possible to calculate the amount of temperature rise of each portion (formed in the longitudinal direction) of the fixing film 1.

Thus, the CPU 32 calculates the amount of temperature rise of each portion (formed in the longitudinal direction) of the fixing film from the amount of heat generation of the portion, by using the induced electromotive force Vd detected by a corresponding one of the detection coils 5A, 5B, and 5C in a period of time from the time t1 to t2; and compares the amount of temperature rise, with the amount of temperature rise detected by a corresponding one of the temperature detection elements 9, 201, and 202. With this operation, the CPU 32 can determine whether the amount of temperature rise is abnormal with respect to the induced electromotive force Vd.

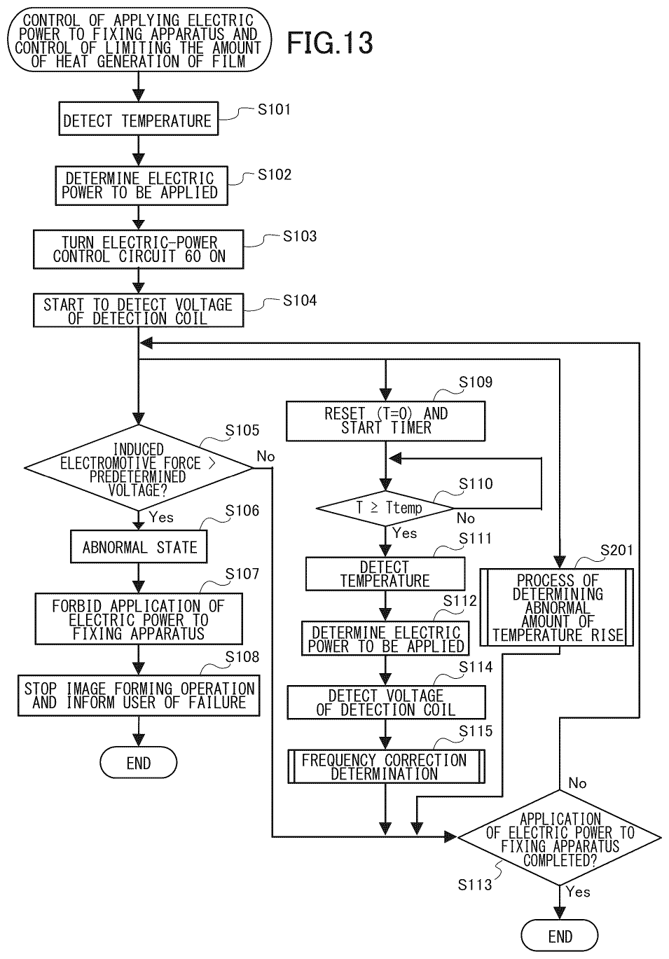

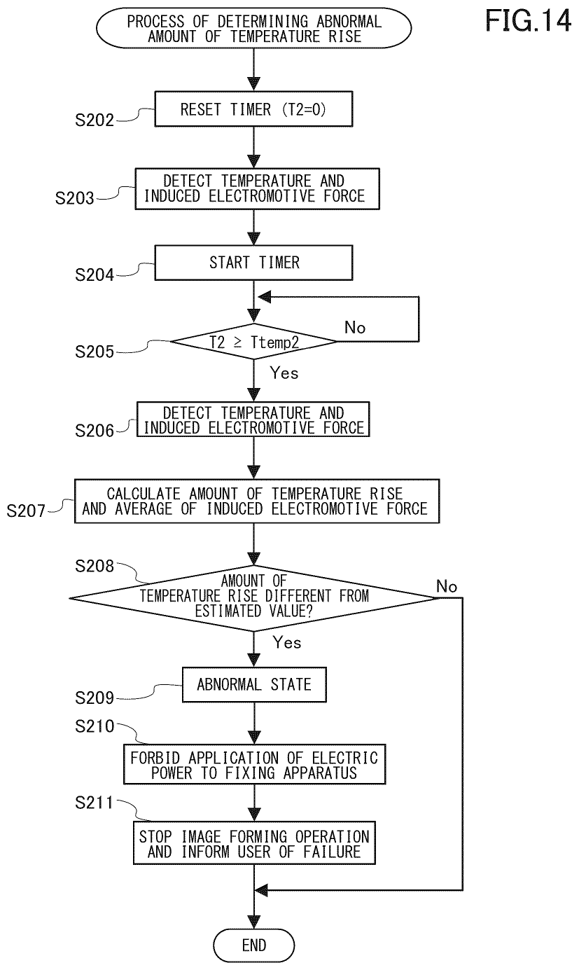

Next, with reference to flowcharts of FIGS. 13 and 14, the control of limiting the amount of heat and the frequency correction control of the present embodiment will be described. In FIG. 13, since the steps S101 to S115 are the same as the steps S101 to S115 of FIG. 9, the description thereof will be omitted. After Step S104, the CPU 32 starts the process of determining an abnormal amount of temperature rise, in parallel with the steps S105 and S109 (S201).

Next, the process of determining an abnormal amount of temperature rise will be described with reference to FIG. 14. If the process of determining an abnormal amount of temperature rise is started, the CPU 32 resets a timer T2 (S202), and stores the values of temperatures detected by the temperature detection elements 9, 201, and 202 when the process is started, and the values of induced electromotive forces detected by the detection coils 5A, 5B, and 5C when the process is started (S203). After that, the CPU 32 starts the timer T2 (S204), and waits until a predetermined time Ttemp2 has elapsed (S205: No). If the predetermined time Ttemp2 has elapsed (S205: Yes), then the CPU 32 stores, again, the values of temperatures detected by the temperature detection elements 9, 201, and 202 when the predetermined time has elapsed, and the values of induced electromotive forces detected by the detection coils 5A, 5B, and 5C when the predetermined time has elapsed (S206).

Then the CPU 32 calculates the amount of temperature rise and an average of the induced electromotive force of each portion (formed in the longitudinal direction) of the fixing film 1 in the predetermined period of time, from the values of temperatures detected by the temperature detection elements 9, 201, and 202 at a time of 0 counted by the timer T2 and a time of Ttemp2 counted by the timer T2, and from the values of the induced electromotive force detected by the detection coils 5A, 5B, and 5C at the time of 0 counted by the timer T2 and the time of Ttemp2 counted by the timer T2 (S207). Then the CPU 32 calculates the estimated amount of temperature rise of each portion (formed in the longitudinal direction) of the fixing film 1 from the average of the induced electromotive force in the period of time from 0 to Ttemp2 counted by the timer T2; and compares the estimated amount of temperature rise, with an actual temperature rise detected by each of the temperature detection elements in the period of time from 0 to Ttemp2 counted by the timer T2 (S208).

If the actual temperature rise is different from the estimated amount of temperature rise (for example, the actual temperature rise is excessively higher or lower than the estimated amount of temperature rise), the CPU 32 determines that the amount of temperature rise of a portion (formed in the longitudinal direction and corresponding to a temperature detection element that has detected an abnormal temperature rise) of the fixing film 1 is abnormal (S209). In this case, the CPU 32 forbids the electric power applied to the fixing apparatus 130 (S210), urgently stops the image forming operation, and informs a user of the error via an operation panel (not illustrated) or the like (S211). If the actual temperature rise is equal to the estimated amount of temperature rise (S208: No), then the CPU 32 determines a normal state, ends the process of determining an abnormal amount of temperature rise, and continues the image forming operation.

As described above, in the present embodiment, it is possible to determine whether the amount of temperature rise of the fixing film 1 is abnormal with respect to the induced electromotive force produced in each detection coil, by comparing the induced electromotive force detected by each detection coil and the amount of temperature rise of each portion of the fixing film 1 in a predetermined period of time. That is, the CPU 32 stops or reduces the electric power supplied to the exciting coil 3, in a case where the relationship between the temperature detected by each of the temperature detection elements 9, 201, and 202 and the induced electromotive force detected by a corresponding one of the detection coils 5A, 5B, and 5C is different from a predetermined relationship. With this operation, if the temperature detected by each temperature detection element is an abnormal temperature, the CPU 32 can determine whether the temperature detection element is in an abnormal state, regardless of the driving frequency of the high-frequency inverter 16 that is controlled. In addition, since the CPU 32 can determine the state even in a state where the temperature detected by each temperature detection element is lower than a target temperature, the CPU 32 can determine the abnormal state in which the temperature detected by each temperature detection element will not reach the target temperature after the CPU 32 starts the printing operation and drives the high-frequency inverter 16, and can inform a user of the failure.

Note that the features described in the above-described embodiments may be combined with each other in any way. In addition, the heating mechanism of the fixing apparatus 130 that serves as an image heating apparatus can be applied not only to the fixing of an image to a recording material, but also to the heating for glossing an image fixed to a recording material, and to the correcting of curling of a recording material on which an image is formed.

The present disclosure can appropriately control the temperature of a rotary member.

### OTHER EMBODIMENTS

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-134496, filed Aug. 9, 2024, which is hereby incorporated by reference herein in its entirety.

What is claimed is:

1. An image heating apparatus configured to heat an image formed on a recording material, the image heating apparatus comprising:
a cylindrical rotary member having conductivity;
a magnetic core disposed in the rotary member and configured to form an open magnetic path in an axis direction of the rotary member;
an exciting coil wound around the magnetic core along the axis direction of the rotary member;
an inverter configured to flow alternating current in the exciting coil;
a control portion configured to control the inverter to cause alternating current to flow through the exciting coil so that alternating magnetic flux is generated in the magnetic core and the rotary member is induction-heated; and
a detection coil in which induced electromotive force is produced by the induced electromotive force being electromagnetically induced by the alternating magnetic flux,
wherein the control portion is configured to change driving frequency of the inverter, and
wherein the control portion is configured to stop or reduce electric power supplied from the inverter to the exciting coil, in a case where a value of the induced electromotive force becomes greater than a predetermined value.

2. The image heating apparatus according to claim 1, wherein the control portion is configured to stop driving of the inverter or decrease driving duty ratio of the inverter, in a case where the value of the induced electromotive force becomes greater than the predetermined value.

3. The image heating apparatus according to claim 1, further comprising:
a temperature detection portion configured to detect a temperature of the rotary member,
wherein the control portion is configured to compare a temperature of the rotary member detected by the temperature detection portion in a predetermined period of time and the induced electromotive force detected by the detection coil in the predetermined period of time, and stop or reduce the electric power supplied from the inverter to the exciting coil, in a case where a relationship between the temperature of the rotary member and the induced electromotive force is different from a predetermined relationship.

4. The image heating apparatus according to claim 3, wherein the control portion is configured to calculate an amount of temperature rise of the rotary member, based on the induced electromotive force detected by the detection coil in the predetermined period of time, and stop or reduce the electric power supplied from the inverter to the exciting coil, in a case where the amount of temperature rise calculated based on the induced electromotive force is different from an amount of temperature rise of the rotary member calculated based on a result detected by the temperature detection portion in the predetermined period of time, by a predetermined value.

5. The image heating apparatus according to claim 1, wherein the detection coil is disposed at a position corresponding to a center portion of the rotary member in a rotation axis direction of the rotary member.

6. The image heating apparatus according to claim 5, further comprising:
a second detection coil where the detection coil is a first detection coil,
wherein the second detection coil is disposed at a position corresponding to an end portion of the rotary member in the rotation axis direction of the rotary member, and an induced electromotive force is produced in the second detection coil by the induced electromotive force being electromagnetically induced by the alternating magnetic flux, and
wherein the control portion is configured to stop or reduce electric power supplied from the inverter to the exciting coil, in a case where a value of the induced electromotive force produced in the second detection coil becomes greater than a predetermined value.

7. The image heating apparatus according to claim 6, wherein the control portion is configured to correct the driving frequency of the inverter for increasing the driving frequency in a case where a difference between the induced electromotive force produced in the first detection coil when the control portion drives the inverter with a predetermined frequency and driving duty ratio and the induced electromotive force produced in the second detection coil when the control portion drives the inverter with the predetermined frequency and driving duty ratio is greater than a predetermined difference.

8. The image heating apparatus according to claim 6, wherein the control portion is configured to correct the driving frequency of the inverter for decreasing the driving frequency in a case where a difference between the induced electromotive force produced in the first detection coil when the control portion drives the inverter with a predetermined frequency and driving duty ratio and the induced electromotive force produced in the second detection coil when the control portion drives the inverter with the predetermined frequency and driving duty ratio is less than a predetermined difference.

9. The image heating apparatus according to claim 1, wherein the control portion is configured to correct the driving frequency of the inverter for increasing the driving frequency in a case where a difference between an amount of heat generation of a center portion of the rotary member obtained when the control portion drives the inverter with a predetermined frequency and driving duty ratio and an amount of heat generation of an end portion of the rotary member obtained when the control portion drives the inverter with the predetermined frequency and driving duty ratio is greater than a predetermined difference.

10. The image heating apparatus according to claim 1, wherein the control portion is configured to correct the driving frequency of the inverter for decreasing the driving frequency in a case where a difference between an amount of heat generation of a center portion of the rotary member obtained when the control portion drives the inverter with a predetermined frequency and driving duty ratio and an amount of heat generation of an end portion of the rotary member obtained when the control portion drives the inverter with the predetermined frequency and driving duty ratio is less than a predetermined difference.

11. The image heating apparatus according to claim 1, wherein the detection coil is configured to be wound around the magnetic core in a space between adjacent turns of the exciting coil.

12. The image heating apparatus according to claim 1, wherein the detection coil is configured to be wound around the exciting coil so as to overlap with the exciting coil in a circumferential direction.

13. An image heating apparatus configured to heat an image formed on a recording material, the image heating apparatus comprising:
a cylindrical rotary member having conductivity;
a magnetic core disposed in the rotary member and configured to form an open magnetic path in an axis direction of the rotary member;
an exciting coil wound around the magnetic core along the axis direction of the rotary member;
an inverter configured to flow alternating current in the exciting coil;
a control portion configured to control the inverter to cause alternating current to flow through the exciting coil so that alternating magnetic flux is generated in the magnetic core and the rotary member is induction-heated;
a detection coil in which induced electromotive force is produced by the induced electromotive force being electromagnetically induced by the alternating magnetic flux; and
a temperature detection portion configured to detect a temperature of the rotary member,
wherein the control portion is configured to compare a temperature of the rotary member detected by the temperature detection portion in a predetermined period of time and an induced electromotive force detected by the detection coil in the predetermined period of time, and stop or reduce electric power supplied from the inverter to the exciting coil, in a case where a relationship between the temperature of the rotary member and the induced electromotive force is different from a predetermined relationship.

14. An image heating apparatus configured to heat an image formed on a recording material, the image heating apparatus comprising:
a cylindrical rotary member having conductivity;
a magnetic core disposed in the rotary member and configured to form an open magnetic path in an axis direction of the rotary member;
an exciting coil wound around the magnetic core along the axis direction of the rotary member;
an inverter configured to flow alternating current in the exciting coil;
a control portion configured to control the inverter to cause alternating current to flow through the exciting coil so that alternating magnetic flux is generated in the magnetic core and the rotary member is induction-heated;
a first heat-generation-amount detection portion configured to detect an amount of heat generation of a center portion of the rotary member; and
a second heat-generation-amount detection portion configured to detect an amount of heat generation of an end portion of the rotary member,
wherein the control portion is configured to correct driving frequency of the inverter for increasing the driving frequency in a case where a difference between the amount of heat generation of the center portion of the rotary member obtained based on a result detected by the first heat-generation-amount detection portion when the control portion drives the inverter with a predetermined frequency and driving duty ratio and the amount of heat generation of the end portion of the rotary member obtained based on a result detected by the second heat-generation-amount detection portion when the control portion drives the inverter with the predetermined frequency and driving duty ratio is greater than a predetermined difference.

15. The image heating apparatus according to claim 11, wherein the control portion is configured to correct driving frequency of the inverter for decreasing the driving frequency in a case where a difference between an amount of heat generation of a center portion of the rotary member obtained when the control portion drives the inverter with a predetermined frequency and driving duty ratio and an amount of heat generation of an end portion of the rotary member obtained when the control portion drives the inverter with the predetermined frequency and driving duty ratio is less than a predetermined difference.

16. An image forming apparatus comprising:
an image forming portion configured to form an image on a recording material; and
the image heating apparatus according to claim 1,
wherein the image heating apparatus is a fixing apparatus configured to fix an image formed on the recording material by the image forming portion, to the recording material by heating and pressing the image.
